(19) United States
(12) Patent Application Publication
(10) Pub. No.: US 2026/0235948 A1
(43) Pub. Date: Aug. 13, 2026

(54) PATTERNED SUBSTRATE PRE-WETTING COMPOSITION, USE OF PRE-WETTING COMPOSITION FOR APPLICATION DIRECTLY ONTO PATTERNED SUBSTRATE, METHOD FOR MANUFACTURING RESIST PATTERN, METHOD FOR MANUFACTURING PROCESSED SUBSTRATE, AND METHOD FOR MANUFACTURING DEVICE

(71) Applicant: Merck Patent GmbH, Darmstadt (DE)

(72) Inventors: Shoji Kuwabara, Shizuoka (JP); Yoshio Nojima, Shizuoka (JP); Hiroshi Hitokawa, Shizuoka (JP)

(21) Appl. No.: 19/153,424

(22) PCT Filed: Feb. 5, 2024
(86) PCT No.: PCT/EP2024/052698

§ 371 Date: Aug. 4, 2025

(30) Foreign Application Priority Data
Feb. 7, 2023 (JP) 2023-016956

(51) Int. Cl. G03F 7/00; G03F 7/09; G03F 7/11; G03F 7/16

(52) U.S. Cl. CPC G03F 7/0035; G03F 7/091; G03F 7/11; G03F 7/168

(57) ABSTRACT

A patterned substrate pre-wetting composition includes 0.05 to 40 mmHg of vapor pressure at 20° C., and 15 to 60 dyn/cm of surface tension at 20° C. Viscosity of the patterned substrate pre-wetting composition at 20° C. is 0.5 to 20.0 cP. The patterned substrate pre-wetting composition contains an organic solvent (A), and optionally, the organic solvent (A) is one organic solvent or a mixture of two or more organic solvents.

### TECHNICAL FIELD

An embodiment of the present invention relates to a patterned substrate pre-wetting composition, the use of the pre-wetting composition for application directly onto a patterned substrate, a method for manufacturing a resist pattern, a method for manufacturing a processed substrate, and a method for manufacturing a device.

### BACKGROUND ART

In the manufacture of devices (electronic components) such as semiconductor devices and liquid crystal display devices, in order to prevent a resolution defect due to reflection from a substrate in a photolithography process (in particular, an exposure process), an underlayer film such as an antireflection film may be formed before a resist film is formed. In Patent Literature 1, a technique is studied in which heat curing of a coating film is advanced from a portion near a substrate by heating, the heating is stopped before the entire coating film is cured, and an uncured portion is removed with a solvent. Patent Literature 2 discusses a technique of using a solution of a resist composition as a pre-wetting agent. A pre-wetting solution for a resist containing cyclohexanone and a compound having a specific structure at a constant mass ratio has been studied in Patent Literature 3. A pre-wetting liquid for a resist that satisfies a predetermined surface tension, viscosity, and vapor pressure is studied as a pre-wetting liquid having excellent resist saving properties in Patent Literature 4.

### CITATION LIST

### Patent Literature

Patent Literature 1: JP2006-320807A
Patent Literature 2: JP2004-39828A
Patent Literature 3: WO2020/170742A
Patent Literature 4: WO2021/059862A

### SUMMARY OF INVENTION

### Technical Problem

A pre-wetting agent used immediately before application of a resist composition has been studied, and application of the pre-wetting agent to a step substrate has not been studied in Patent Literatures 2, 3, and 4. An underlayer film formed under a resist film may not be formed on a surface of a substrate with good coverage depending on the shape of the substrate (for example, in the case of a patterned substrate in which a pattern is formed in advance).

In view of the above problems, the present invention is directed to at least one of the following: forming an underlayer film on a patterned substrate with good coverage; forming the underlayer film on the patterned substrate with good conformality; suppressing variations in portions of a resist pattern affected by standing waves and portions of the resist pattern not affected by standing waves; improving a yield of a method for manufacturing an element; providing a patterned substrate pre-wetting composition having sufficient storage stability; preventing the occurrence of cracks of the underlayer film; obtaining volatility suitable for coating the underlayer film; and improving a good wettability to the surface of the patterned substrate.

### Solution to Problem

According to an embodiment, a patterned substrate pre-wetting composition wherein vapor pressure at 20° C. is 0.05 to 40 mmHg and surface tension at 20° C. is 15 to 60 dyn/cm is provided.

According to an embodiment of the present invention, the use of a pre-wetting composition for application directly onto a patterned substrate is provided.

According to an embodiment of the present invention, a method for manufacturing a resist pattern, including: preparing a patterned substrate; applying a patterned substrate pre-wetting composition directly on the patterned substrate; applying an underlayer film composition on the patterned substrate to form an underlayer film; optionally heating the underlayer film; forming a resist film directly on the underlayer film; and processing the resist film to form a resist pattern is provided.

According to an embodiment of the present invention, a method for manufacturing a processed substrate, including manufacturing a resist pattern by the method described above, and processing using the resist pattern as a mask is provided.

According to an embodiment of the present invention, a method for manufacturing a device including the method for manufacturing the processed substrate described above is provided.

### Effects of Invention

An underlayer film can be formed on a patterned substrate with good coverage by using an embodiment of the present invention. An underlayer film can be formed on a patterned substrate with good conformality by using an embodiment of the present invention. A yield of a resist pattern can be improved by using an embodiment of the present invention. Variations between portions of a resist pattern affected by standing waves and portions of the resist pattern not affected by standing waves can be suppressed by using an embodiment of the present invention. A yield of a method for manufacturing a device can be improved by using an embodiment of the present invention. A patterned substrate pre-wetting composition having sufficient storage stability can be provided by using an embodiment of the present invention. The occurrence of cracks in the underlayer film can be prevented by using an embodiment of the present invention. Volatility suitable for coating an underlayer film can be obtained by using an embodiment of the present invention. Wettability to a surface of a patterned substrate can be improved by using an embodiment of the present invention.

### BRIEF DESCRIPTION OF DRAWINGS

FIG. 1A is a schematic cross-sectional view showing a manufacturing method of a resist pattern according to an embodiment of the present invention.

FIG. 1B is a schematic cross-sectional view showing a manufacturing method of a resist pattern according to an embodiment of the present invention.

FIG. 1C is a schematic cross-sectional view showing a manufacturing method of a resist pattern according to an embodiment of the present invention.

FIG. 1D is a schematic cross-sectional view showing a manufacturing method of a resist pattern according to an embodiment of the present invention.

FIG. 1E is a schematic cross-sectional view showing a manufacturing method of a resist pattern according to an embodiment of the present invention.

FIG. 2 is a schematic cross-sectional view after formation of an underlayer film according to an embodiment of the present invention.

FIG. 3 is a schematic cross-sectional view for evaluating conformality.

FIG. 4 is a SEM image of an example of a patterned substrate on which an underlayer film is formed, which is evaluated as A in an example of the present invention.

FIG. 5 is a SEM image of an example of a patterned substrate on which an underlayer film is formed, which is evaluated as C in the example of the present invention.

### DESCRIPTION OF EMBODIMENTS

Hereinafter, a patterned substrate pre-wetting composition, the use of a pre-wetting composition for coating a patterned substrate directly onto the patterned substrate, a method for manufacturing a resist pattern, a method for manufacturing a processed substrate, and a method for manufacturing a device according to embodiments of the present invention will be described in detail with reference to the drawings. In addition, the following embodiments are examples of embodiments of the present invention, and the present invention is not to be construed as being limited to these embodiments.

In addition, in the drawings attached to the present specification, the shape, the scale, the aspect ratio, and the like of each part may be changed or exaggerated from the actual one in order to facilitate understanding.

### Definition

In this specification, unless stated to the contrary, the definitions and examples set forth in this paragraph are as follows.

The singular form includes the plural form. The singular forms “a,” “an,” or “the” means “at least one”. An element of a concept can be expressed by a plurality of species. If amounts (for example, mass % or mol %) are described, the amounts refer to a sum of the species.

“And/or” includes all combinations of elements and also includes single use.

In the case where numerical ranges are indicated using “to” or “-”, these include both endpoints and units are common. For example, 5 to 25 mol % means 5 mol % or more and 25 mol % or less.

The descriptions such as “Cx to y”, “Cx to Cy” and “Cx” refer to a number of carbons in a molecule or substituent. For example, C1 to C6 alkyl refers to alkyl chains having 1 or more and 6 or less of carbons (for example, methyl, ethyl, propyl, butyl, pentyl, hexyl, and the like).

In the case where a polymer has more than one type of repeating unit, these repeating units are copolymerized. This copolymerization may be any of alternating copolymerization, random copolymerization, block copolymerization, graft copolymerization, or a mixture thereof. When a polymer or a resin is represented by a structural formula, n, m, and the like shown in parentheses indicate a number of repetitions.

Temperature is measured in degrees Celsius (Celsius). For example, 20° C. means 20° C. Celsius.

As used herein, the term “patterned substrate” refers to a substrate in which a pattern having a predetermined shape is formed in advance. Thus, the pattern herein refers to a pattern formed by processing a surface of the substrate, and preferably does not include a pattern formed from another film or layer on the substrate. For example, it is preferable that an aspect in which a resist pattern made of only an organic material is formed on a bare wafer is not included in the pattern. However, in the case where a metal film, an oxide film, or a nitride film is deposited on a flat substrate and processed to such an extent that the flat substrate is not exposed, it is also included in the patterned substrate. The surface of the substrate before being processed may be treated with oxidation or nitridation of the metal.

As used herein, the term “patterned substrate pre-wetting composition” refers to a composition that is applied within a top surface of a substrate pattern and gaps (also referred to as “space”) between the patterns, and more preferably forms an underlayer film thereafter.

In the present specification, “conformality” means that, in the case where a substrate having a pattern having a pattern width 500 nm, a pattern width 500 nm and a height 100 nm is used, a ratio (X/Y) of a film thickness (X) of an underlayer film on a top portion of a substrate pattern wall to a film thickness (Y) of an underlayer film on a bottom portion of a groove between pattern walls is 0.20 to 0.99.

In the present specification, the term “coverage” means that, in the case where a substrate having a pattern width 500 nm, a spacing width 500 nm, and a height 100 nm is used, a distance from a corner portion of the top portion (top end portion) of the pattern wall to an end portion of the underlayer film on the top portion of the pattern wall is 0 to 70 nm.

### [1. Pre-Wetting Composition for Patterned Substrate]

In a patterned substrate pre-wetting composition according to an embodiment of the present invention, vapor pressure at 20° C. is 0.05 to 40 mmHg, preferably 0.5 to 40 mmHg, more preferably 1 to 30 mmHg, further preferably 1 to 20 mmHg, and further more preferably 1.3 to 8 mmHg. Also, surface tension at 20° C. of the patterned substrate pre-wetting composition is 15 to 60 dyn/cm, preferably 22 to 47 dyn/cm, more preferably 22 to 30 dyn/cm, and still more preferably 23 to 28 dyn/cm. The patterned substrate pre-wetting composition is preferably used immediately before a formation of an underlayer film. The underlayer film means a film formed under a resist film and on the substrate. The underlayer film is preferably a Bottom Anti Reflective Coating (BARC) film, a planarization film, an adhesion enhancing film, or a high-carbon film (SOC; Spin on Carbon film) (more preferably, BARC film or SOC film, still more preferably BARC film). Hereinafter, each component of the patterned substrate pre-wetting composition will be described.

In a patterned substrate pre-wetting composition according to an embodiment of the present invention, viscosity at 20° C. is 0.5 to 20.0 cP, preferably 0.7 to 18 cP, more preferably 1.0 to 15 cP, and still more preferably 1.2 to 12 cP.

A patterned substrate pre-wetting composition according to an embodiment of the present invention contains an organic solvent (A). The organic solvent (A) is preferably one organic solvent or a mixture of two or more organic solvents. Particularly, the organic solvent (A) is preferably one selected from the group consisting of an alcohol solvent, an ether solvent, an ester solvent, a ketone solvent, and a hydrocarbon solvent, or any combination of these solvents.

In the case where an alcohol solvent is used as the organic solvent (A), the alcohol solvent is preferably n-propanol, i-propanol (IPA), n-butanol, i-butanol, sec-butanol, t-butanol, n-pentanol, i-pentanol, 2-methylbutanol, sec-pentanol, t-pentanol, 3-methoxybutanol, or n-hexanol.

In the case where an ether solvent is used as the organic solvent (A), the ether solvent is preferably propylene glycol monoalkyl ethers such as propylene glycol monomethyl ether (PGME), ethylene glycol monomethyl ether, ethylene glycol monoethyl ether, ethylene glycol diethyl ether, and propylene glycol monoethyl ether (PGEE), dibutyl ether, or dioxane.

In the case where an ester solvent is used as the organic solvent (A), the ester solvent is preferably methyl lactate, ethyl lactate (EL), γ-butyrolactone, n-propyl acetate, n-butyl acetate, i-butyl acetate, sec-butyl acetate, n-pentyl acetate, or propylene glycol 1-monomethyl ether 2-acetate (PGMEA).

In the case where a ketone solvent is used as the organic solvent (A), the ketone solvent is preferably 2-pentanone, 3-pentanone, methyl isobutyl ketone, 2-heptanone, 2-hexanone, 4-heptanone, diisobutyl ketone, cyclopentanone, or cyclohexanone.

In the case where a hydrocarbon solvent is used as the organic solvent (A), the hydrocarbon solvent is preferably toluene, heptane, octane, methylcyclohexane, or ethylcyclohexane.

The organic solvent (A) of the present invention is preferably an ether solvent, an ester solvent, or a mixture thereof (more preferably an ether solvent or an ester solvent).

The organic solvent (A) is preferably PGME, EL, n-butanol, butyl acetate, cyclopentanone, toluene, n-pentanol, n-hexanol, or a mixture of any of these, more preferably PGME, EL, n-pentanol, n-hexanol, or a mixture of any of these, still more preferably PGME, EL or a mixture of these, and even more preferably PGME or EL.

In the case where the organic solvent (A) is a mixture of two compounds, a volume ratio is preferably from 95:5 to 5:95, more preferably from 90:10 to 10:90, even more preferably from 80:20 to 20:80, even more preferably from 70:30 to 30:70.

The content of the organic solvent (A) contained in the patterned substrate pre-wetting composition is preferably 95 to 100 mass %, more preferably 97 to 100 mass %, and still more preferably 99 to 100 mass % compared to the total patterned substrate pre-wetting composition. It is even more preferred that the patterned substrate pre-wetting composition consists essentially of the organic solvent (A).

The patterned substrate pre-wetting composition may further include an additive (B). The additive (B) is a compound different from the component (A). The additive (B) is preferably highly volatile. Particularly, the additive (B) is preferably vaporized when the organic solvent (A) is vaporized, or before or after the vaporization of the organic solvent (A), but not limited thereto. A content of the additive (B) contained in the patterned substrate pre-wetting composition is 0 to 5 mass %, preferably 0 to 3 mass %, and more preferably 0 to 1 mass % compared to the total pre-wetting composition for the patterned substrate. In an embodiment of the present invention, it is needless to say that there is an aspect whereby the content of the additive (B) in the entire patterned substrate pre-wetting composition is 0 mass %, i.e. the entire patterned substrate pre-wetting composition does not include the additive (B), and it is desirable that the patterned substrate pre-wetting composition does not include the additive (B).

The additive (B) may be selected from a surfactant, an acid, a base, a substrate adhesion enhancer, a defoamer, or any combination of any of these. Hereinafter, the additive (B) will be described in detail.

### [Surfactants]

If the surfactant is contained as the additive (B) in the patterned substrate pre-wetting composition, the coating property to the substrate can be improved. The content of the surfactant contained in the patterned substrate pre-wetting composition is 0 to 2 mass %, preferably 0 to 1 mass %, and more preferably 0 to 0.5 mass % with respect to the organic solvent (A).

Any surfactant can be used. For example, an anionic surfactant, a cationic surfactant, or a nonionic surfactant can be used as the surfactant. More particularly, alkyl sulfonates, alkyl benzene sulfonic acids, and alkyl benzene sulfonates, lauryl pyridinium chloride, lauryl methyl ammonium chloride, polyoxyethylene octyl ether, polyoxyethylene lauryl ether, or polyoxyethylene acetylenic glycol ether are preferably used as the surfactant. A nonionic alkyl ether surfactant manufactured by Nippon Nyukazai is commercially available as a nonionic surfactant.

### [Acid or Base]

In the case where the patterned substrate pre-wetting composition includes an acid or base as additive (B), it is possible to improve the properties of the patterned substrate pre-wetting composition, such as adjusting the pH of the patterned substrate pre-wetting composition. The acid or base may be prepared according to a material of the substrate to which the patterned substrate pre-wetting composition is applied and added to the patterned substrate pre-wetting composition. A content of the acid or base contained in the patterned substrate pre-wetting composition is 0 to 1 mass %, preferably 0 to 0.5 mass %, and more preferably 0 to 0.2 mass % with respect to the organic solvent (A).

The acid or base can be arbitrarily selected within a range that does not impair the effects of the present invention. For example, carboxylic acids, amines, or ammonium salts can be used as the acid or base. Carboxylic acids, amines, or ammonium salts herein include fatty acids, aromatic carboxylic acids, primary amines, secondary amines, tertiary amines, or ammonium compounds, which may be substituted by any substituent. More particularly, formic acid, acetic acid, propionic acid, benzoic acid, phthalic acid, salicylic acid, lactic acid, malic acid, citric acid, oxalic acid, malonic acid, succinic acid, fumaric acid, maleic acid, aconitic acid, glutaric acid, adipic acid, monoethanolamine, diethanolamine, triethanolamine, triisopropanolamine, or tetramethylammonium can be used as the acid or base.

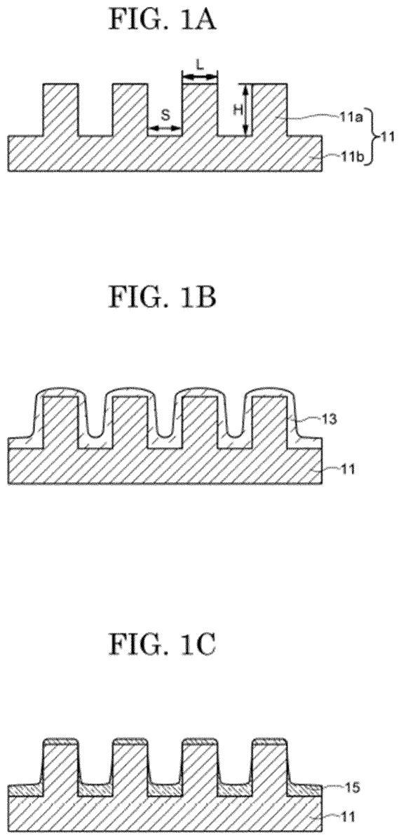

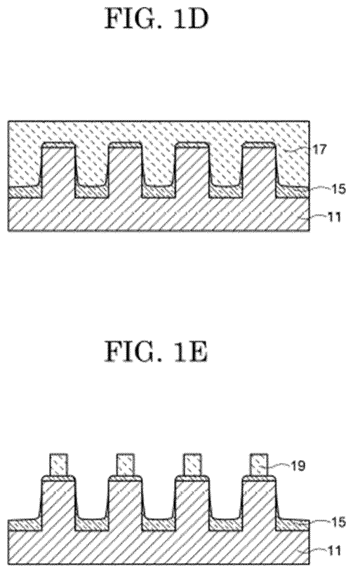

In the patterned substrate pre-wetting composition according to an embodiment of the present invention, the patterned substrate includes two adjacent patterns and a space between the two adjacent patterns. In FIG. 1A, in the case where a pattern width L is defined as a length (diameter in the case of a circular dot) of a top portion of a pattern 11a in a short-side direction and a space width S is defined as a distance between pattern bottom portions of neighboring patterns 11a, and a ratio (L/S) between the pattern width L and the space width S is preferably 1/100 to 100, more preferably 1/20 to 20, still more preferably 1/10 to 10, and still more preferably ⅕ to 5.

Further, L/S may be different depending on a pattern shape. Particularly, in the case where a patterned substrate 11 has a line-and-space shaped pattern, the pattern width L is the space width S or less (the pattern width L≤the space width S), and L/S is preferably 1/10 to 1, and more preferably ⅕ to 1. In the case where the patterned substrate has a slit-shaped pattern, the pattern width L≥the space width S, and L/S is preferably 1 to 10, and more preferably 15. In the case where the patterned substrate has a dot-shaped pattern, the pattern width L≤the space width S, and L/S is preferably 1/100 to 1, and more preferably 1/20 to 1.

A mechanism based on the patterned substrate pre-wetting composition of the above configuration is not bound by theory, but is inferred as follows.

It is considered that the patterned substrate pre-wetting composition of the present invention has a surface tension of a certain value or more, so that the underlayer film composition applied to the top portion of the pattern walls of the substrate pattern can avoid falling between the pattern walls due to be absorbed to the pre-wetting composition too much. In addition, since the surface tension of the patterned substrate pre-wetting composition is a constant value or less, it is considered that the underlayer film composition applied on the top portion of the pattern wall in the substrate pattern is repelled by the pre-wetting composition and the underlayer film composition can be prevented from falling from the top portion of the pattern.

As one embodiment, it is considered that since the vapor pressure of the patterned substrate pre-wetting composition of the present invention is within a certain range, the pre-wetting composition can be appropriately left in the substrate pattern when the underlayer film composition is applied.

For the above reasons, it is presumed that good coverage and conformability of the underlayer film composition on the patterned substrate can be realized by using the patterned substrate pre-wetting composition of the present invention.

### [2. Use of Pre-Wetting Composition]

In the use of a pre-wetting composition for applying directly onto a patterned substrate according to an embodiment of the present invention, vapor pressure at 20° C. of the pre-wetting composition may be the same as the vapor pressure at 20° C. of the patterned substrate pre-wetting composition described above. Similarly, surface tension may be the same as the surface tension at 20° C. of the patterned substrate pre-wetting composition described above.

### [3. Method for Manufacturing Resist Pattern]

Referring to FIG. 1A to FIG. 1E, the use of a patterned substrate pre-wetting composition according to an embodiment of the present invention will be described.

First, the patterned substrate 11 is prepared as shown in FIG. 1A. The patterned substrate 11 includes the pattern 11a and a unit 11b serving as a base of the pattern 11a, and the pattern 11a and the unit 11b serving as the base are made of the same material and are integrated.

A method for forming the pattern 11a formed on the patterned substrate 11 can be arbitrarily selected from known methods such as photolithography and dry etching. Various pretreatments can be combined in the formation of the pattern 11a.

A shape of the patterned substrate 11 is not particularly limited, and the patterned substrate 11 may have any shape of a line and space, a slit, or a dot. The dot has a columnar shape, and may have a square pole shape or a cylindrical shape. A height H of the pattern 11a (perpendicular distance from the bottom portion to the top portion of the pattern) is preferably 0.01 to 300 μm, preferably 0.01 to 200 μm, and more preferably 0.01 to 150 μm.

In the case where a pattern width L is defined as a length (diameter in the case of circular dot) in a short-side direction at the top portion of the pattern, an aspect ratio (L/H) between the pattern width L and the pattern height H is preferably 1/100 to 100, preferably 1/20 to 20, more preferably 1/10 to 10, still more preferably ⅕ to 5, and still more preferably 1 to 5.

In the case where the pattern width L is defined as the length (diameter in the case of circular dots) at the top portion of the pattern 11a in the short-side direction and the space width S is defined as the distance between the pattern bottom portions of the adjacent patterns 11a, the ratio (L/S) between the pattern width L and the space width S may be L/S in the patterned substrate pre-wetting composition described above, and L/S may be changed according to the pattern shapes as described above.

The patterned substrate 11 may be formed of any one of a semiconductor, an oxide, a nitride, a metal, or any combination thereof. Therefore, a material of the patterned substrate 11 is not particularly limited, but is, for example, Ge, SiGe, SiO₂, TiO₂, Al₂O₃, SiON, HfO₂, Ta₂O₅, HfSiO₄, Y₂O₃, GaN, TiN, TaN, Si₃N₄, NbN, Cu, Ta, W, Hf, or Al.

The patterned substrate 11 may have a structure in which a plurality of layers are stacked. In this example, the patterned substrate 11 may have a structure in which an oxide layer is formed on a semiconductor. In this case, a pattern may be formed on an oxide layer arranged on a silicon substrate.

The patterned substrate 11 may be a glass substrate for a liquid crystal display device, a glass substrate for an organic EL display device, a glass substrate for a plasma display, a substrate for an optical disk, a substrate for a magnetic disk, a substrate for a magneto-optical disk, a glass substrate for a photomask, or a substrate for a solar cell.

Next, as shown in FIG. 1B, a pre-wetting composition 13 is applied directly onto the patterned substrate 11. The pre-wetting composition is preferably formed by a spin coating method. In the present embodiment, it is more preferable to use PGME or EL among those described above for the pre-wetting composition. In this specification, unless otherwise described, in the description of the method, the term “directly above” means not to interpose an interlayer, and the term “above” includes both a state in which the intermediate layer is interposed and a state in which the intermediate layer is not interposed.

In addition, in the present embodiment, a hydrophilization treatment may be performed to a surface of the patterned substrate 11 before the pre-wetting composition is applied. For example, as the hydrophilization treatment, an aqueous solution of 2.38% tetramethylammonium hydroxide (TMAH) may be contacted with the surface of the patterned substrate 11. As a result, hydrophilic groups (OH groups) can be terminated on the surface of the patterned substrate 11, and a wettability of the surface can be enhanced.

Next, as shown in FIG. 1C, an underlayer film 15 is formed by applying the underlayer film composition to the patterned substrate 11. In this case, immediately before applying the underlayer film composition, the pre-wetting composition 13 may remain on the entire surface of the patterned substrate 11. or may partially remain on the surface of the patterned substrate 11. Preferably, the pre-wetting composition 13 does not form a layer or a film. The underlayer film composition is preferably applied by dropping into a center of the substrate. In this case, it is preferable that the substrate is rotating. Without being bound by theory, it is considered that the pre-wetting composition 13 present on the patterned substrate 11 helps the underlayer film composition to become wet and spread with good coverage and/or conformality when the underlayer film composition is coated. The pre-wetting composition 13 itself present on the patterned substrate 11 is preferably removed from the substrate in a form extruded by the underlayer film composition when the underlayer film composition is coated.

The underlayer film composition contains an aminoplast and a multifunctional alcohol. The aminoplast may contain glycoluril, melamine, or benzoguanamine.

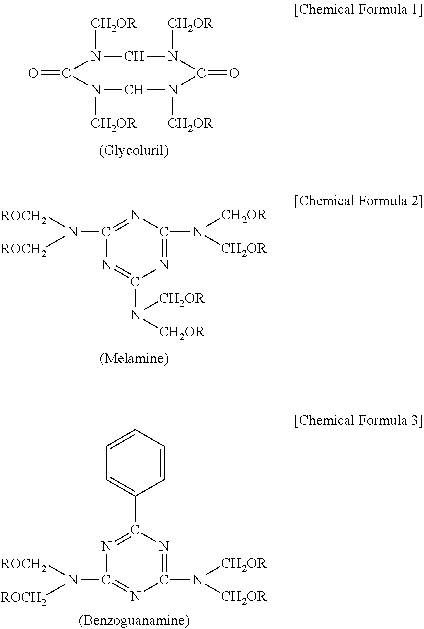

The polyfunctional alcohol may be polymer A or polymer C.

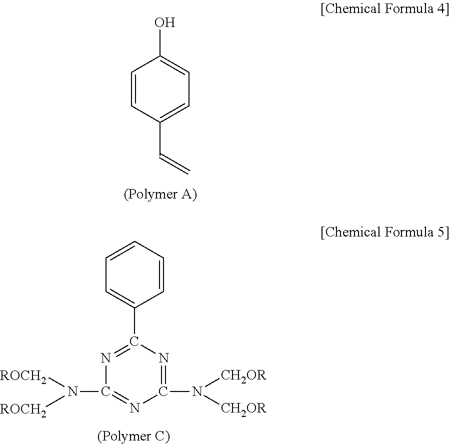

In the present embodiment, it is desirable to apply the underlayer film composition before the pre-wetting composition 13 is volatilized. Without being bound by theory, it is considered that since the underlayer film composition applied to the substrate spreads while being mixed and dissolved with the pre-wetting composition 13, the underlayer film composition tends to easily wet and spread on the surface of the substrate.

Next, the underlayer film 15 is heat-treated. The heating temperature is 80 to 280° C., preferably 100 to 240° C., and more preferably 120 to 200° C. The heating time may be 30 to 180 seconds. Thus, the underlayer film 15 is cured. In addition, in the heat treatment, a plurality of stages of heat treatment may be performed using a plurality of temperatures. A thickness of the underlayer film 15 after being heated is 1 nm to 500 nm, preferably 2 nm to 200 nm, more preferably 4 nm to 100 nm, and still more preferably 5 nm to 50 nm. In this embodiment, the thickness of the underlayer film 15 is 22 nm. The formed underlayer film 15 has an (n) value of 1.60 to 1.90, preferably 1.65 to 1.85, and more preferably 1.70 to 1.80 in an optical parameter measured by light at a wavelength of 248 nm. A (k) value is 0.05 to 0.40, preferably 0.10 to 0.35, and more preferably 0.15 to 0.30 in the optical parameter measured by light with a wavelength of 248 nm. Thus, the underlayer film 15 can be used as a BARC film. The BARC film can improve cross-sectional shapes and exposure margins. In addition, in the case where the underlayer film 15 is used as an etching mask, the underlayer film 15 preferably has etching resistance.

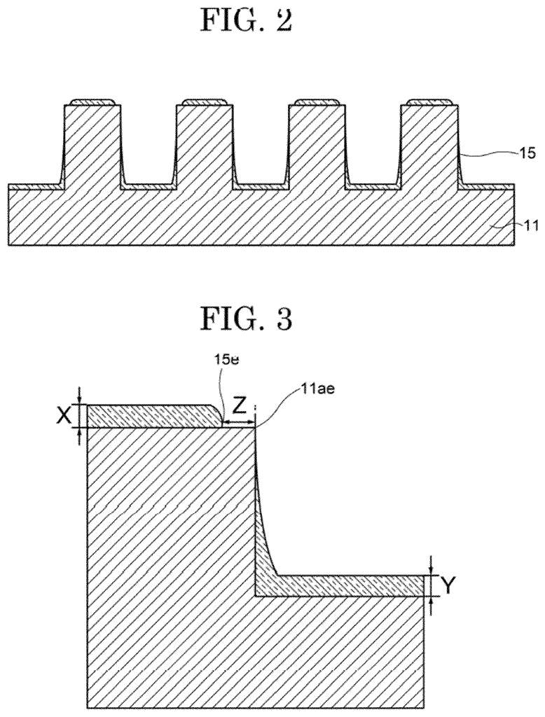

In the present embodiment, the underlayer film 15 is formed conformally on the patterned substrate 11. FIG. 2 is a schematic view of a underlayer film formed on the patterned substrate 11. In the present embodiment, the underlayer film 15 does not necessarily have to be present on a top end portion to a portion of an inner side, and a side surface (wall) portion of the pattern as shown in FIG. 2. FIG. 3 is a schematic view showing the coverage and the conformability. In FIG. 3, for example, a distance from a corner portion (top end portion) 11ae of the top portion in the pattern wall 11a to an end portion 15e of the underlayer film 15 on the top portion of the pattern wall 11a is 0 to 70 nm, preferably 0 to 50 nm, more preferably 0 to 40 nm, further preferably 0 to 30 nm, and further more preferably 0 to 20 nm. A ratio (X/Y) between a film thickness (X) of the underlayer film 15 on a pattern wall and a film thickness (Y) of the underlayer film at the bottom of the groove between the pattern walls is 0.20 to 0.99, preferably 0.25 to 0.99, more preferably 0.40 to 0.99, and still more preferably 0.50 to 0.99.

In the present specification, it is preferable to confirm coverage and conformality as described in the embodiment, and more particularly, it is preferable to confirm the coverage and conformality using a substrate having a pattern width of 500 nm/a space width of 500 nm and a height of 100 nm.

Next, as shown in FIG. 1D, a resist film 17 is coated and formed on the patterned substrate 11. A film thickness of the resist film 17 is preferably 50 to 500 nm, preferably 80 to 400 nm, and more preferably 100 to 300 nm. The resist film 17 may be subjected to a heat treatment.

Next, as shown in FIG. 1E, the resist film 17 is processed to form a resist pattern 19. The resist pattern 19 can be formed by combining known methods (for example, photolithography).

When etching the patterned substrate 11, the underlayer film 15 and the patterned substrate 11 are preferably etched at once using the resist pattern 19 as a mask. Alternatively, after the underlayer film 15 is etched using the resist pattern 19 as a mask, the patterned substrate 11 (more particularly, the top portion of the pattern wall in the patterned substrate and/or the groove between the pattern walls; more particularly, and more preferably, the top portion of the pattern wall) may be etched using the underlayer film 15 as a mask. The etching may be wet etching or dry etching (more preferably dry etching). As a result, a processed substrate in which a new pattern is formed on the patterned substrate 11 can be manufactured.

A device can be manufactured by further processing the processed substrate described above. Examples of the device include a semiconductor device, a liquid crystal display device, an organic EL display device, a plasma display device, and a photovoltaic device. The device is preferably a semiconductor device. Known methods can be used for these processes. After the device is formed, the substrate can be cut into chips, connected to a lead frame, and packaged with a resin, if desired. One example of this package is a semiconductor device.

From the above, since the wettability of the patterned substrate 11 is improved by using a pre-wetting composition according to an embodiment of the present embodiment, it is possible to enhance coverage and conformality with respect to the patterned substrate 11 of the underlayer film 15.

### [Modification]

Within the scope of the present invention, those skilled in the art can conceive of various modifications and examples, and it is understood that these modifications and examples also fall within the scope of the present invention. For example, additions or deletions of constituent elements, combinations of embodiments, or design changes made by those skilled in the art, or additions to processes, omissions, or condition changes to each embodiment described above by those skilled in the art as appropriate are also included in the scope of the present invention as long as they have the gist of the present invention.

Although the BARC film is used as the underlayer film 15 in an embodiment of the present invention, the present invention is not limited thereto. The underlayer film 15 may be a coated carbon film (also referred to as a coated C film, a Spin On Carbon film, referred to as a SOC film). A coated carbon film layer 12 may be formed by coating using a known method such as spin coating, followed by pre-baking.

### EXAMPLES

Hereinafter, a patterned substrate pre-wetting composition according to an embodiment of the present invention will be described in more detail based on Examples. In addition, a patterned substrate pre-wetting composition according to an embodiment of the present invention is not limited to the following examples.

### Preparation Example of Underlayer Film Composition 1

3 g of poly(4-vinylphenol) (Polymer A, Merck) and 1 g of tetramethoxymethyl glycol uril (Tokyo Chemical Industry, TCI hereinafter) are dissolved in 66.95 g of PGMEA/29 g of PGME solvent to obtain solutions.

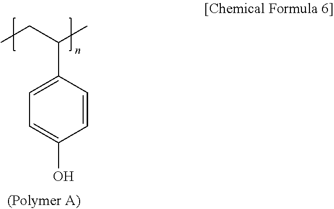

0.05 g of dodecyl benzenesulfonic acid/triethylamine (mol ratio 1:1) is added to the polymeric solutions. This mixture is then filtered through a 0.2 μm pore size microfilter and a Solution 1 is obtained. 40 pts. mass of PGMEA and 25 pts. mass of PGME are added to 35 pts. mass of Solution 1 and mixed. This mixture is filtered through a 0.2 μm pore size microfilter and an underlayer film composition 1 is obtained.

### Synthesis Example B of Polymer B

600 g of tetramethoxymethyl glycol uril (TCI) and 96 g of styrene glycol (TCI) are charged into 1200 g of PGMEA in a 2L volume jacketed flask equipped with a thermometer, mechanical stirrer and cold water condenser. The flask is heated to 85° C. The flask is removed and a catalytic amount of para-toluenesulfonic acid monohydrate is added from the top of the flask and maintained at 85° C. for 5 hours to proceed the reaction. This reaction solution is returned to room temperature and filtered to give a filtrate. The filtrate is slowly poured into an ion exchange water while stirring to precipitate the polymer. This polymer is filtered, washed thoroughly with water and dried in a decompression furnace. 250 g of Polymer B are obtained. The resulting Polymer B is confirmed to have a weight average molecular weight of about 17,345 and a polydispersity of 2.7.

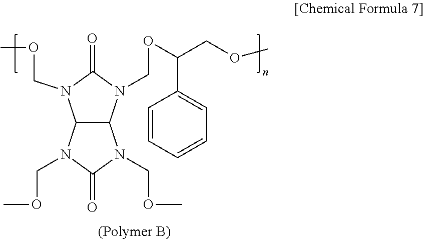

### Synthesis Example C of Polymer C

20 g of butane tetracarboxylic dianhydride (Fujifilm Wako Pure Chemical Industries), 20 g of (+)-dimethyl L-tartrate (TCI), and 1.0 g of benzyl tributyl ammonium chloride (TCI) are charged into 70 g of PGMEA to obtain a liquid. The liquid is charged into a flask equipped with a condenser, a temperature controller and a mechanical stirrer. The liquid in the flask is stirred in a nitrogen atmosphere and this liquid is heated to 110° C. A clear solution is obtained after 1 to 2 hours. The temperature is maintained at 110° C. for 4 hours. The solution is cooled to 60° C. 40 g of PGMEA, 60 g of acetonitrile, 68 g of propylene oxide (TCI) and 30 g of tris(2,3-epoxypropyl) isocyanurate (Merck) are added to the above solutions and mixed. The reaction proceeds at 52° C. for 40 hours. The reaction solution is cooled to room temperature. The reaction solution is slowly poured into a large amount of water in a high speed blender. The precipitated polymer is collected and washed thoroughly with water. The polymer is dried in a decompression furnace. 40 g of a polymer C are obtained. The polymer C having a weight average molecular weight of about 32,000 is obtained.

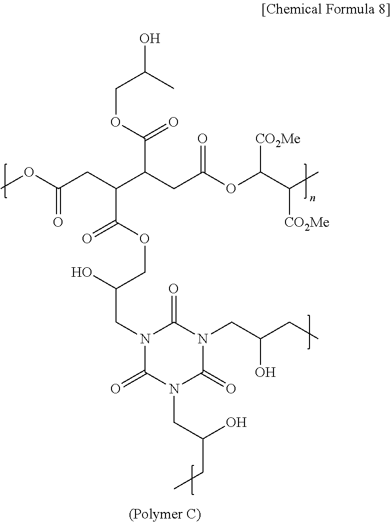

### Preparation Example 2 of Underlayer Film Composition 2

68.95 g of PGMEA and 27 g of PGME are mixed to obtain a mixed liquid. 3 g of the Polymer B and 1 g of the Polymer C are added to the mixed liquid to obtain solutions. 0.05 g of dodecyl benzenesulfonic acid (TCI)/triethylamine (TCI) (mol ration 1:1) is added to the solutions and dissolved. This is filtered through a 0.2 μm pore size microfilter and Solution 2 is obtained. 40 pts. mass of PGMEA and 25 pts. mass of PGME are added to 35 pts. mass of Solution 2 and mixed. This mixture is filtered through a 0.2 μm pore size microfilter and an underlayer film composition 2 is obtained.

### Preparation Example of Wafer on which Underlayer Film is Formed. Examples 1 to 9

A4-inch silicon wafer having a pattern with a pattern width 500 nm/a space width 500 nm (1:1 line and space) and a height 100 nm made of SiO₂ is prepared. This wafer is immersed in the aqueous solution of 2.38% TMAH for 10 seconds, washed with pure water, and dried to hydrophilize a patterned surface.

The hydrophilized wafer is placed in a spin coater (MS-B200, Mikasa). The program is set to rotate the wafer at 500 rpm for 15 seconds and then 1500 rpm for 20 seconds. A spin coater is started by dropping the respective 2 mL of pre-wetting compositions listed in Table 1 below to a center of the wafer. After 5 seconds, 2 mL of respective underlayer film composition described in the tables are dropped for 5 seconds in the middle of the wafer (in rotation) with the pre-wetting composition sufficiently coated on the patterned wafer. The underlayer film composition is coated onto the wafer by rotating the wafer according to a set program.

This wafer is heated on a hotplate at 110° C. for 60 seconds. This wafer is further heated on a hotplate at 200° C. for 60 seconds. Thus, a wafer on which a cured underlayer film is formed is obtained.

### Preparation Example of Wafer on which Underlayer Film is Formed. Comparative Example 1

A wafer having a cured underlayer film formed thereon is obtained by a method same manner as that of Examples 1 to 9, except that the pre-wetting composition is not used and the program setting conditions are changed as follows.

The hydrophilized wafer is placed in a spin coater (MS-B200). The program is set so that the wafer is rotated at 500 rpm for 5 seconds and then rotated at 1500 rpm for 20 seconds. The dripping of pre-wetting composition for the patterned substrate is not performed. A spin coater is started by dropping 2 mL of the underlayer film described in Table 1.

### Preparation Example of SEM Sections and Observation

The section for SEM of the wafer on which the underlayer film was formed is observed using an electron-microscope SU8230 (Hitachi High-Tech) at a magnification of 200K times.

### [Evaluation of Conformality]

Based on the Preparation Example of the SEM Sections and Observation, the conformity is evaluated as follows. As shown in the schematic diagram of FIG. 3, a thickness X (nm) of an underlayer film at a point 250 nm from a corner portion of a top portion in a pattern wall is measured. A thickness Y (nm) of a BARC film at a point 250 nm from a corner portion of a bottom portion in a groove between pattern walls is also measured. According to (X/Y), the conformality is evaluated on the basis of the following evaluation criteria. Evaluation results are listed in Table 1.

TABLE 1

| | Example 1 | Example 2 | Example 3 | Example 4 | Example 5 | Example 6 |
|---|---|---|---|---|---|---|
| BARC film | Underlayer | Underlayer | Underlayer | Underlayer | Underlayer | Underlayer |
| | film | film | film | film | film | film |
| | composition 1 | composition 1 | composition 1 | composition 1 | composition 1 | composition 1 |
| Prewet agent | PGME | Ethyl lactate | n-butanol | Butyl acetate | Cyclopentanone | Toluene |
| Viscosity | 1.8 | 2.6 | 3.0 | 0.7 | 1.1 | 0.6 |
| (cP, 20° C.) | | | | | | |
| Vapor | 6.7 | 1.6 | 4.39 | 9 | 8.63 | 21.7 |
| Pressure | | | | | | |
| (mmHg, | | | | | | |
| 20° C.) | | | | | | |
| Surface | 27.1 | 29.2 | 24.6 | 25.09 | 33.3 | 28.53 |
| Tension | | | | | | |
| (dyn/cm, | | | | | | |
| 20° C.) | | | | | | |
| X nm | 22.6 | 21.5 | 19.4 | 10.9 | 7.4 | 5.9 |
| Y nm | 35 | 37.7 | 35.5 | 30.3 | 22.8 | 23.9 |
| X/Y | 0.65 | 0.57 | 0.55 | 0.36 | 0.32 | 0.25 |

| | | | | | | Comparative |
|---|---|---|---|---|---|---|
| | Example 7 | Example 8 | Example 9 | Example 10 | Example 11 | Example 1 |
| BARC film | Underlayer | Underlayer | Underlayer | Underlayer | Underlayer | Underlayer |
| | film | film | film | film | film | film |
| | composition 2 | composition 1 | composition 1 | composition 1 | composition 1 | composition 1 |
| Prewet agent | PGME | n-pentanol | n-hexanol | Isopropanol | Ethylene glycol | Not used |
| Viscosity | 1.8 | 3.4 | 5.2 | 2.4 | 20.0 | — |
| (cP, 20° C.) | | | | | | |
| Vapor | 6.7 | 1.5 | 0.6 | 32.4 | 0.08 | — |
| Pressure | | | | | | |
| (mmHg, | | | | | | |
| 20° C.) | | | | | | |
| Surface | 27.1 | 25.6 | 24.5 | 21.7 | 46.49 | — |
| Tension | | | | | | |
| (dyn/cm, | | | | | | |
| 20° C.) | | | | | | |
| X nm | 20.6 | 15.2 | 14.7 | 5.4 | 6.2 | 4.5 |
| Y nm | 34 | 26.6 | 28.7 | 25.7 | 29.3 | 26.7 |
| X/Y | 0.61 | 0.57 | 0.51 | 0.21 | 0.21 | 0.17 |

As shown in Table 1, the larger a value of X/Y, the thicker the underlayer film is formed on the top portion of the pattern. This means that the conformality is higher (classified as “A”). The evaluation criteria are as follows.
A: (X/Y)≥0.5 Has sufficient conformity.
B: 0.20≤(X/Y)<0.5 Has a certain degree of conformality.
C: (X/Y)<0.20 Conformality is insufficient.

### [Evaluation of Coverage]

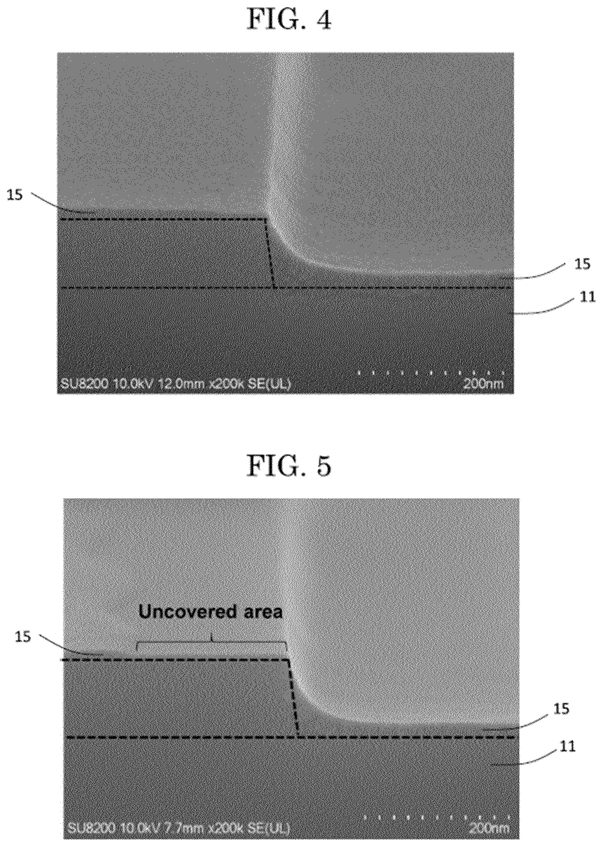

Based on the Preparation Example of SEM section and Observation, the coverage is evaluated as follows. In the case where the corner portion of the top portion (top end portion) in the pattern wall was not covered with the underlayer film, a distance from a corner portion (top end portion) of an uncovered area to an end portion of the underlayer film was defined as Z (nm), and a length of Z was measured. The evaluation criteria are as follows. Evaluation results are listed in Table 2. FIG. 4 is a SEM image (observation photograph) of an example of a patterned substrate on which a underlayer film is formed, which is evaluated as A in the evaluation of coverage. FIG. 5 is a SEM observation photograph of an example of a patterned substrate on which an underlayer film is formed, which is evaluated as C in the evaluation of coverage.

TABLE 2

| | Example 1 | Example 2 | Example 3 | Example 4 | Example 5 |
|---|---|---|---|---|---|
| BARC | Underlayer | Underlayer | Underlayer | Underlayer | Underlayer |
| | film | film | film | film | film |
| | composition 1 | composition 1 | composition 1 | composition 1 | composition 1 |
| Prewet agent | PGME | Ethyl lactate | n-butanol | Butyl acetate | Cyclopentanone |
| Viscosity | 1.8 | 2.6 | 3 | 0.7 | 1.1 |
| (cP, 20° C.) | | | | | |
| Vapor | 6.7 | 1.6 | 4.39 | 9 | 8.63 |
| Pressure | | | | | |
| (mmHg, 20° C.) | | | | | |
| Surface | 27.1 | 29.2 | 24.6 | 25.09 | 33.3 |
| Tension | | | | | |
| (dyn/cm, 20° C.) | | | | | |
| Z nm | 0 | 0 | 0 | 18.4 | 47.5 |
| | | | | | Comparative |
| | Example 6 | Example 7 | Example 8 | Example 9 | Example 1 |
| BARC | Underlayer | Underlayer | Underlayer | Underlayer | Underlayer |
| | film | film | film | film | film |
| | composition 1 | composition 2 | composition 1 | composition 1 | composition 1 |
| Prewet agent | Toluene | PGME | n-pentanol | n-hexanol | Not used |
| Viscosity | 0.6 | 1.8 | 3.4 | 5.2 | |
| (cP, 20° C.) | | | | | |
| Vapor | 21.7 | 6.7 | 1.5 | 0.6 | — |
| Pressure | | | | | |
| (mmHg, 20° C.) | | | | | |
| Surface | 28.53 | 27.1 | 25.6 | 24.5 | — |
| Tension | | | | | |
| (dyn/cm, 20° C.) | | | | | |
| Z nm | 46.7 | 0 | 0 | 0 | 74.3 |

A: Z=0 The corner portion of the top portion in the pattern wall is completely covered by the underlayer film.
B: 0<Z≤50 The corner portion of the top portion in the pattern wall is not completely covered with the underlayer film and is partially exposed. It has a certain degree of coverage.
C: Z>50 The corner portion of the top portion of the pattern wall is not covered with the underlayer film and is largely exposed.
The coverage is insufficient (FIG. 5).

As can be seen from Table 2, the Examples 1 to 9 are better than the Comparative Example 1 as the patterned substrate pre-wetting composition in terms of coverage.

### REFERENCES SIGNS LIST

11: patterned substrate
13: pre-wetting composition
15: underlayer film
17: resist film
19: resist pattern

1. A patterned substrate pre-wetting composition comprising:
0.05 to 40 mmHg of vapor pressure at 20° C.; and
15 to 60 dyn/cm of surface tension at 20° C.

2. The patterned substrate pre-wetting composition according to claim 1, wherein
viscosity of the patterned substrate pre-wetting composition at 20° C. is 0.5 to 20.0 cP.

3. The patterned substrate pre-wetting composition according to claim 1, wherein
the patterned substrate pre-wetting composition contains an organic solvent (A), and
optionally, the organic solvent (A) is one organic solvent or a mixture of two or more organic solvents.

4. The patterned substrate pre-wetting composition according to claim 3, wherein
the organic solvent comprised in the organic solvent (A) is an alcohol solvent, an ether solvent, an ester solvent, a ketone solvent, a hydrocarbon solvent, or any combination of these solvents.

5. The patterned substrate pre-wetting composition according to claim 3, wherein
the organic solvent comprised in the organic solvent (A) contains at least one of the group consisting of propylene glycol monomethyl ether, ethyl lactate, n-pentanol, and n-hexanol.

6. The patterned substrate pre-wetting composition according to claim 1, further comprising:
an additive (B), wherein
optionally, the additive (B) is selected from a surfactant, an acid, a base, a substrate adhesion enhancer, a defoaming agent, or any combination of any of these, and
optionally, a content of the additive (B) is 0 to 3 mass % compared to the total pattern substrate pre-wetting composition.

7. The patterned substrate pre-wetting composition according to claim 1, wherein
the patterned substrate includes two adjacent patterns and a space between the two patterns, and
a ratio between a pattern width and a space width is 1/100 to 100.

8. A method comprising:
applying a pre-wetting composition directly onto a patterned substrate, wherein the pre-wetting composition comprises
vapor pressure at 20° C. is 0.05 to 40 mmHg; and
surface tension at 20° C. is 15 to 60 dyn/cm.

9. A method for manufacturing a resist pattern comprising:
preparing a patterned substrate;
applying a patterned substrate pre-wetting composition directly onto the patterned substrate;
applying an underlayer film composition on the patterned substrate to form an underlayer film;
optionally heating the underlayer film;
forming a resist film directly on the underlayer film; and
processing the resist film to form a resist pattern.

10. The method for manufacturing the resist pattern according to claim 9, wherein
the underlayer film composition contains an aminoplast and a multifunctional alcohol.

11. The method for manufacturing the resist pattern according to claim 10, wherein
the aminoplast contains glycoluryl, melamine, or benzoguanamine.

12. The method for manufacturing the resist pattern according to claim 9, further comprising:
performing a hydrophilic treatment of a surface of the patterned substrate when preparing the patterned substrate.

13. The method for manufacturing the resist pattern according to claim 9, further comprising:
heating the underlayer film at 80 to 280° C. for 30 to 180 seconds.

14. The method for manufacturing the resist pattern according to claim 9, wherein
the patterned substrate includes two adjacent patterns and a space between the two patterns,
a ratio between a pattern width and a space width is 1/100 to 100, and
a ratio (X/Y) between a thickness (X) of the underlayer film on the patterns and a thickness (Y) of the underlayer film on the space is 0.20 to 0.99.

15. The method for manufacturing the resist pattern according to claim 14, wherein
a distance from a top end portion of the pattern to an end portion of the underlayer film on the pattern is 0 to 70 nm.

16. The method for manufacturing the resist pattern according to claim 9, wherein
an optical constant of the underlayer film measured by light at a wavelength of 248 nm satisfies an (n) value of 1.60 to 1.90 and/or a (k) value of 0.05 to 0.40.

17. A method for manufacturing a processed substrate comprising:
manufacturing a resist pattern by the method of claim 9; and
processing the resist pattern as a mask.

18. The method for manufacturing the processed substrate according to claim 17, wherein
an object to be processed using the resist pattern as a mask is a patterned substrate or an underlayer film, and
optionally, when the object to be processed is a patterned substrate, a target location is a top portion of a pattern wall of the patterned substrate or a groove between pattern walls.

19. A method for manufacturing a device comprising:
the method for manufacturing the processed substrate according to claim 18.

20. The method for manufacturing the resist pattern according to claim 13, wherein
the underlayer film is heated at 120 to 200° C. for 30 to 180 seconds.
